(19) United States
(12) Patent Application Publication
(10) Pub. No.: US 2017/0284725 A1
(43) Pub. Date: Oct. 5, 2017

(54) CRYOSTAT WITH A FIRST AND A SECOND HELIUM TANK, WHICH ARE SEPARATED FROM ONE ANOTHER IN A LIQUID-TIGHT MANNER AT LEAST IN A LOWER PART

(71) Applicant: Bruker BioSpin GmbH, Rheinstetten (DE)

(72) Inventors: Patrick WIKUS, Nuerensdorf (CH); Marco STROBEL, Karlsruhe (DE); Gerhard ROTH, Rheinstetten (DE)

(21) Appl. No.: 15/619,044

(22) Filed: Jun. 9, 2017

Related U.S. Application Data
(63) Continuation of application No. PCT/EP2015/078280, filed on Dec. 2, 2015.

(30) Foreign Application Priority Data
Dec. 10, 2014 (DE) 10 2014 225 481.7

(51) Int. Cl. F25D 19/00; G01R 33/38; F25B 9/02

(52) U.S. Cl. CPC F25D 19/00; F25B 9/02; G01R 33/3804

(57) ABSTRACT

A cryostat for subcooled (<2.5 K) liquid helium includes two separate helium tanks. A Joule-Thomson cooling unit includes a heat exchanger in the lower part of the first helium tank and uses liquid stored in the second helium tank in order to cool the subcooled liquid helium stored in the lower part of the first helium tank. The Joule-Thomson cooling unit draws in liquid helium either directly from the second helium tank or from the first helium tank, which is replenished via the gas phase from the second helium tank. In this way, the subcooled liquid helium of the first helium tank can be cooled for a long time from a combined stock of liquid helium in the first helium tank and the second helium tank. The second helium tank may be arranged adjacent or surrounding the first helium tank to maintain a lower overall height of the cryostat.

### CROSS REFERENCE TO RELATED APPLICATIONS

This is a Continuation of International Application PCT/EP2015/078280, which has an international filing date of Dec. 2, 2015, and the disclosure of which is incorporated in its entirety into the present Continuation by reference. The following disclosure is also based on and claims the benefit of and priority under 35 U.S.C. §119(a) to German Patent Application No. 10 2014 225 481.7, filed Dec. 10, 2014, which is also incorporated in its entirety into the present Continuation by reference.

### FIELD OF THE INVENTION

The invention relates to a cryostat for holding subcooled liquid helium.

### BACKGROUND

Nuclear magnetic resonance (NMR) equipment, in particular NMR spectrometers and NMR tomographs, requires strong magnetic fields, which are often generated by superconducting magnet coils. The superconducting magnet coils must be operated at a cryogenic temperature. To this end, the superconducting magnet coils are typically arranged in the cryogenic tank of a cryostat, which is filled with a cryogenic liquid.

Particularly low temperatures in the cryostat can be achieved using liquid helium. Helium boils under atmospheric pressure at a temperature of approx. 4.2 K. In order to achieve temperatures of less than 4.2 K, pumping can be carried out with respect to a liquid helium bath. The reduction in vapor pressure leads to cooling of the bath. This approach has the drawback that there is sub-atmospheric pressure in the helium tank. In the case of incorrect operation or a small leak in the system, this can have serious consequences, such as drawing in of air, freezing the air in the interior of the system, blockage of discharge lines.

Liquid helium can also be produced at a temperature of less than 2.5 K, in particular in the superfluid state, using a Joule-Thomson cooling unit. In practice, as described for example in German Patent No. DE 102010028750 B4, a helium tank is typically filled in a lower first chamber (lower part) with liquid helium at approx. 2 K and in an upper, second chamber (upper part) with liquid helium at approx. 4.2 K. A heat-insulating barrier separates the two chambers. A Joule-Thomson cooling unit draws in liquid helium from the upper or lower chamber, expands it, and then cools the lower chamber of the helium tank. The expanded helium is pumped away. This system prevents the generation of sub-atmospheric pressure in the entire helium tank; there is sub-atmospheric pressure only in the relatively small Joule-Thomson cooling unit. For this purpose, a thermal barrier provides thermal insulation, but transfers the pressure of the upper tank to the lower tank. These conditions may occur if the thermal barrier is permeable to liquid helium or is configured as a thermally insulating membrane. From a thermodynamic standpoint, the helium in the lower tank is “subcooled,” i.e., the actual pressure is greater than the vapor pressure corresponding to the temperature.

For cooling the lower part of the helium tank, the Joule-Thomson cooling unit consumes liquid helium, causing the filling level in the upper part of the helium tank to drop. Recycling a portion of the pumped-off helium into the upper part, as proposed in DE 102010028750 B4, reduces the helium consumption of the cryostat. Even in this case, however, the helium tank must still be refilled with helium at regular intervals. Refilling of the liquid helium is cumbersome for the user. In addition, a high-resolution NMR system can only be used to a limited extent for a few days after refilling the helium tank. Refilling the helium tank should therefore be carried out as rarely as possible.

In general, the frequency with which liquid helium must be refilled can be reduced by enlarging the upper part of the helium tank so that it can store a large amount of helium at 4.2 K and can thus cool the lower part of the helium tank for a longer period. This increases the overall height of the cryostat. In typical laboratories, however, the maximum overall height of the cryostat may be limited by the existing ceiling height. Greater ceiling heights would result in high renovation costs in the laboratory building, if renovation is even possible.

In order to further limit helium consumption, it is possible to recycle the pumped-off helium via an additional active cooling device, such as a pulse tube cooler, which allows the upper part to be refilled with the recondensed helium that was pumped off. In the event of failure or repair of the active cooling device, however, the Joule-Thomson cooling unit consumes the liquid helium of the upper part as well, and the volume of the upper part of the helium tank limits the period of time during which a failure of the active cooling device can be tolerated while maintaining cooling by the Joule-Thomson cooling unit. In order to increase this period of time, the overall height of the cryostat must again be increased.

If it is provided to introduce a probe device into a room temperature bore of the cryostat from above the cryostat, a free space above the cryostat approximately equal to the height of the upper part of the helium tank must be provided, which further reduces the maximum overall height of the cryostat with respect to the available ceiling height in a laboratory area.

The Japanese Patent Publication No. JP 2001330328 A discloses a cryostat in which a tank for superfluid helium is arranged under a tank for normal fluid helium and is separated by a separator. The tank for normal fluid helium is divided into a first helium tank and a second helium tank, with the first helium tank being separated from the tank for superfluid helium by the separator. At the bottom of the second helium tank a tube connects to the first helium tank. With this cryostat, the heat input into the tank for superfluid helium is to be reduced, and at the same time, a good capacity of the tank for normal fluid helium is to be ensured.

### SUMMARY

The techniques presented herein provide a cryostat in which a large amount of liquid helium for operating a Joule-Thomson cooling unit can be stored without having to increase the overall height of the cryostat. The cryostat comprises a first helium tank, which is filled in a lower part with liquid helium, in particular superfluid helium, at a temperature <2.5 K. The upper part of the first helium tank is at least partially with liquid helium, in particular normal fluid helium, at a temperature >4 K. In this way, the first helium tank has a first region that is continuously filled with liquid helium between the lower end of the lower part and a first liquid surface in the upper part. The cryostat also includes a Joule-Thomson cooling unit to cool the liquid helium in the lower part of the first helium tank by expansion of helium via a heat exchanger.

The cryostat further comprises a second helium tank, which is at least partially filled with liquid helium, in particular normal fluid helium, at a temperature >4 K. The second helium tank has a second region that is continuously filled with liquid helium between a lower end of the second helium tank and a second liquid surface in the second helium tank. The first helium tank and the second helium tank are separated from each other in a liquid-tight manner at least below the liquid surfaces. The Joule-Thomson unit for cooling the lower part of the first helium tank can withdraw liquid helium from the second helium tank either
directly by drawing liquid helium in from the second helium tank,
or indirectly by evaporating liquid helium from the second helium tank, recondensing the evaporated helium in the upper part of the first helium tank, and drawing liquid helium from the first helium tank.

### BRIEF DESCRIPTION OF THE DRAWINGS

The invention is shown in the drawing and will be explained in further detail using examples. The figures show the following:

FIG. 1 is a schematic cross-sectional view of a first example of a cryostat, with a Joule-Thomson cooling unit drawing on the first helium tank and a common gas chamber of the two helium tanks;

FIG. 2 is a schematic cross-sectional view of a second example of a cryostat, with a Joule-Thomson cooling unit drawing on the second helium tank and separate gas chambers of the two helium tanks;

FIG. 3 is a schematic cross-sectional view of a third example of a cryostat, with a Joule-Thomson cooling unit drawing on the second helium tank and a common gas chamber of the two helium tanks;

FIG. 4 is a schematic cross-sectional view of a fourth example of a cryostat, with two separate filling funnels for filling the helium tanks;

FIG. 5 is a schematic cross-sectional view of a fifth example of a cryostat, with two filling tubes for filling the helium tanks having a common coupling station for a rotatable transfer rod;

FIG. 6 is a schematic cross-sectional view of a sixth example of a cryostat, with an active cooling device above the second helium tank;

FIG. 7 is a schematic cross-sectional view of a seventh example of a cryostat, with a first helium tank having a narrowed access tube; and

FIG. 8 is a schematic cross-sectional view of an eighth example of a cryostat, with a room temperature horizontal bore.

### DETAILED DESCRIPTION

The cryostat described herein provides a second helium tank, in addition to the first helium tank. The second tank provides a further supply of liquid helium at a temperature >4 K, in addition to the supply of liquid helium at a temperature >4 K in the upper part of the first helium tank. This further supply can be used to cool the lower part of the first helium tank, i.e. to cool the liquid helium in the first helium tank to a temperature <2.5 K. The cryostat is configured such that liquid helium can be directly or indirectly withdrawn from the second helium tank for cooling the first helium tank.

Access to the second helium tank can take place directly via the Joule-Thomson cooling unit. In other words, the liquid helium contained in the second helium tank may flow into a supply line, for example, from the bottom of the second helium tank, reaching the Joule-Thomson cooling unit or the needle valve thereof. At the needle valve, which is connected to a pump line, the liquid helium expands and cools. A heat exchanger in the pump line, which is arranged in the lower part of the first helium tank (e.g., above a magnet coil), cools the liquid helium in the lower part of the first helium tank. It should be noted that in this case, the needle valve is typically arranged outside the two helium tanks (e.g., in a “divided arrangement”).

Alternatively, the Joule-Thomson cooling unit may draw liquid helium from the first helium tank and supply it to the needle valve of the Joule-Thomson cooling unit. At the needle valve, which in this case as well is connected to a pump line, the liquid helium again expands and cools. A heat exchanger in the pump line is arranged in the lower part of the first helium tank (e.g., above a magnet coil), and cools the liquid helium in the lower part of the first helium tank. In one example, a supply line of the Joule-Thomson cooling unit is fed into the upper part of the first helium tank so that warmer liquid helium at >4 K is drawn in. Alternatively, the supply line may draw in subcooled liquid helium at <2.5 K from the lower part; in this case, the lower part of the first helium tank is filled with liquid helium from the upper part of the first helium tank (through a thermal barrier). The upper part of the first helium tank is then filled by helium evaporating from the second helium tank. The evaporated helium from the second helium tank recondenses in the upper part of the first helium tank. In one example, the recondensed helium drips down from a partial section of the pump line into the upper part of the first helium tank. In another example, the liquid surface in the first helium tank remains constant as long as the additional supply of liquid helium in the second helium tank is not exhausted. For this purpose, a connection to carry helium gas may be configured between a first gas chamber above the liquid surface of the first helium tank and a second gas chamber above the liquid surface of the second helium tank, so that the two helium tanks include a common gas chamber for gaseous helium. Alternatively, only recondensed liquid helium may be transferred from the second gas chamber into the upper part of the first helium tank.

According to another example, the lower, liquid-carrying regions of the first helium tank and the second helium tank are separated from each other in a liquid-tight manner. In other words, the liquid chambers of the first and second helium tank do not communicate with each other. In particular, there is no connection to carry liquid helium between the first region of the first helium tank and the second region of the second helium tank.

According to a further example, valves do not separate the liquid chambers of the two tanks. Valved connections would be technically challenging, and the consequences of the failure or accidental opening of a valve may be catastrophic, for example, if a current-carrying superconducting magnet coil in the lower part of the first helium tank loses its coolant. Accordingly, the liquid levels (i.e. the absolute position of the liquid surfaces) in the first helium tank and the second helium tank are independent from each other. In particular, during operation, the liquid level in the second tank may drop below the liquid level in the first tank.

The second helium tank may be placed in the cryostat largely independently of the first helium tank. In particular, the second helium tank does not have to be arranged at the same level as the upper part of the first helium tank. Accordingly, the second helium tank may be placed such that the overall height of the cryostat is not changed. For example, the second helium tank may be arranged laterally to the first helium tank, and in particular laterally to the lower part of the first helium tank.

A superconducting magnet coil may be placed in the lower part of the first helium tank. The cryostat arrangement may be used in particular in an NMR apparatus. The second helium tank may be thermally insulated at least from the lower part of the first helium tank, for example, by vacuum insulation.

The liquid surfaces in the two helium tanks are preferably at a temperature of about 4 K, which corresponds to a vapor pressure of approximately 1 bar. In practice, the pressure of the helium gas above the liquid surfaces is typically actively regulated so that it is slightly (e.g., 10-50 mbar) above atmospheric pressure (i.e., ambient air pressure). In the case of small leaks, this overpressure prevents any impurities from penetrating into the cryogenic vessel. If the first helium tank and the second helium tank do not have communicating gas chambers, the pressure may be regulated separately in the first helium tank and the second helium tank.

In one example of the cryostat described herein, the second helium tank is at least partially arranged laterally adjacent to the first helium tank and/or at least partially arranged surrounding the first helium tank. In particular, the second helium tank may be arranged completely or partially adjacent to the lower part of the first helium tank and/or around the lower part of the first helium tank. By arranging the second helium tank horizontally adjacent to the first helium tank or surrounding it, the overall height of the cryostat is not increased, resulting in a more compact cryostat architecture overall.

In another example, the first helium tank and the second helium tank are arranged such that the first liquid surface of the liquid helium in the first helium tank can be at a higher level than the second liquid surface of the liquid helium in the second helium tank. In this case, space in the second helium tank located at a level lower than the upper part of the first helium tank can be used for the storage of liquid helium at >4 K.

In particular, the liquid level in the second helium tank (“storage tank”) may drop below the level of the upper edge of the superconducting magnet coil in the first helium tank, which is not possible in typical cryostats.

In a further example, the capacity of the second helium tank for liquid helium is at least three times greater than that of the upper part of the first helium tank. In this case, the supply of liquid helium for the operation of the Joule-Thomson cooling unit may be significantly increased. Accordingly, the large supply of liquid helium in the second helium tank allows for particularly long intervals between refilling liquid helium or a longer downtime of an additional (with respect to the Joule-Thomson cooling unit) active cooling device (e.g., a pulse tube cooler).

In yet another example, a thermal barrier is arranged between the upper part and the lower part of the first helium tank. A temperature gradient of at least 1 Kelvin is produced, generating an interface between the superfluid helium and the normal fluid helium. By means of the thermal barrier (e.g., a glass-fiber-reinforced plastic plate with several through holes for liquid helium), the heat input into the lower part can be kept low, while allowing a (typically slower) transfer of liquid helium from the upper into the lower region. The liquid helium in the upper part exerts (gravitational) pressure through the thermal barrier onto the liquid helium in the lower part, allowing the liquid helium in the lower part to be subcooled (with respect to the helium vapor pressures over the upper part). In one example, the degree of thermal insulation between the lower part and the upper part may be regulated or allowed to self-regulate based on the position of an interface between the superfluid helium and the normal fluid helium within the thermal barrier.

In still a further example, the first helium tank comprises an access tube that is narrower than a section of the first helium tank lying thereunder. A temperature gradient may be established in the access tube of at least 1 Kelvin, allowing the interface between the superfluid helium and the normal fluid helium to be present in the access tube. This moves the boundary between the upper part and the lower part of the first helium to the access tube. In the narrowed access tube, heat exchange between the upper part and the lower part is limited to a small cross-sectional area compared to the cross-sectional area of the section of the first helium tank lying under the access tube. The limited heat exchange results in an insulating effect for the lower part of the first helium tank. Accordingly, a thermal barrier at the interface between the superfluid helium and the normal fluid helium may be unnecessary. The (horizontal) cross-sectional area in the narrowed access tube is typically a maximum of 1/10, and preferably a maximum of 1/20 of the cross-sectional area of the section of the first helium tank lying thereunder.

In another example, the cryostat comprises a room temperature vertical bore. The first helium tank is arranged surrounding the room temperature vertical bore, and the second helium tank may be arranged surrounding the first helium tank. This design saves space and has been proven to be effective in practice. Since a probe device is typically introduced from above into the room temperature bore, an upper part of the first helium tank with a low height minimizes any free space required as introduction space above the cryostat. A vertical bore is often selected for high-resolution NMR spectroscopy; in this case, liquid samples are usually tested that can be easily introduced via the vertical bore.

Alternatively, the cryostat may comprise a horizontal room temperature bore. The second helium tank is arranged horizontally adjacent to the first helium tank, such that the room temperature horizontal bore extends into both the first helium tank and the second helium tank. This design is suitable for particularly low ceiling heights of laboratory areas, since a probe device may be laterally introduced. Horizontal bores are typically used in imaging methods in medicine and research; the typical research subjects, such as humans, mice, rats, etc., can be particularly easily introduced into horizontal bores.

In one example, the Joule-Thomson cooling unit liquid directly draws helium from the second helium tank, for example, from a lower end of the second helium tank. This design is relatively simple, because the cryostat does not need to be specifically configured for evaporation, convection, and recondensation of helium gas needs. In this example, a common gas chamber of the first and second helium tanks is not required, but may be configured if desired. The second helium tank includes an outlet on the underside of the second helium tank through which the liquid helium flows into the valve (e.g., needle valve) of the Joule-Thomson cooling unit, typically via a supply line. The supply line is selected to be long enough that the temperature levels of the second helium tank (approx. 4.2 K) and the Joule-Thomson cooling unit (<2.5 K) are sufficiently insulated from each other. The helium evaporates in the valve, and the cold vapor is guided by a heat exchanger through the lower region of the first helium tank and cools the lower region of the first helium tank.

In another example, a first gas chamber of the first helium tank and a second gas chamber of the second helium tank are connected to exchange helium gas. By connecting the first gas chamber (above the first liquid surface in the first helium tank), the second gas chamber (above the second liquid surface in the second helium tank), and any other helium-gas-carrying connecting sections of the cryostat, a common gas chamber is formed in the cryostat above the helium tanks. Under normal operating conditions, cold helium gas may flow from the second helium tank to the first helium tank and condense into the first helium tank. In this example, the Joule-Thomson cooling unit may draw liquid helium from the first helium tank (e.g., from the upper part, or from the lower part). In this example, the pressure is regulated at only one location—typically by means of a heater. The heater is preferably arranged in the second helium tank. Helium that evaporates from the second helium tank can then condense in the first helium tank.

In embodiment further example, the helium flow rate for the Joule-Thomson cooling unit drawing liquid helium from the first helium tank, such that at the given heat loads on the first and second helium tank corresponding to said helium flow rate, liquid helium evaporates from the second helium tank and recondenses in the upper part of the first helium tank. In other words, the liquid level in the first tank does not change. This principle is feasible because on expansion of helium from approximately 1 bar to approximately 10 mbar (i.e., the typical pressure change behind the valve of the Joule-Thomson cooling unit), more cooling capacity becomes available than that required for condensation at constant pressure (of approx. 1 bar). The difference in cooling capacity is then available for the absorption of external heat loads.

In still another example, the upper part of the first helium tank and the second helium tank are separated by a wall, which has an overflow edge to allow the liquid helium to overflow from the first helium tank into the second helium tank. In this configuration, recondensation can be focused on the upper part of the first helium tank, which can be achieved by means of a simple structure. The second helium tank is (re)filled by overflow from the first helium tank. The wall is typically part of a vacuum insulation.

In a further example, the cryostat comprises an active cooling device, such as a pulse tube cooler, that liquifies helium evaporated from the first helium tank and/or from the second helium. The active cooling device, which is in addition to the Joule-Thomson-cooling device, liquefies and recycles gaseous helium that has evaporated, has been brought in from outside the cryostat, or has been expanded by the Joule-Thomson cooling unit. For instance, the cryostat may be operated with a closed helium circuit (i.e., without helium loss in normal operation). The liquefied helium is (again) available for operation of the Joule-Thomson cooling unit. If a common gas chamber of the two helium tanks is provided, the active cooling device may liquify the helium gas in this common gas chamber. If the first and second helium tank have separate (e.g., mutually sealed off) gas chambers, the helium gas is typically liquefied in the gas chamber of the second helium tank. The helium gas may liquefy from a cooling stage of the active cooling device, and then drip down into first helium tank or the second helium tank.

In this case, the active cooling device may be configured in the cryostat such that failure of the active cooling device transfers a greater heat load to the second heating tank than the first helium tank. In this way, failure of the active cooling device evaporates more helium from the second helium tank than from the first helium tank. This delays exposure of the superconducting magnet coil in the lower part of the helium tank to higher temperatures, and thus delays quenching the superconducting magnet coil. In order to reduce the evaporation of helium from the first helium tank, a connection having good thermal conductivity (such as a metal rod assembly, e.g., of copper) can be provided from a heat-introducing element to the second region of the second helium tank.

For this purpose, the active cooling device may be arranged above the second helium tank, with the first liquid surface completely or predominantly shielded from the active cooling device. For instance, a wall that is part of the vacuum insulation of the cryostat may shield the first liquid surface from the active cooling device. This causes thermal radiation from the active cooling device to be brought primarily into the second liquid surface of the second tank lying under the active cooling device rather than into the first liquid surface. This can be configured by means of a relatively simple construction.

In another example, a pump line of the Joule-Thomson cooling unit runs through the upper part of the first helium tank and then, at least with a partial section, runs into a gas chamber above the first helium tank. In this configuration, helium liquefied on the outside of the pump line in the partial section can drip from the pump line into the upper part of the first helium tank. This provides a simple way to refill the upper part of the first helium tank with the recondensed liquid helium. If the gas chambers of the first helium tank and the second helium tank are separated from each other, the pump line may be first guided with a partial section into the gas chamber of the first helium tank, and then with a further partial section into the gas chamber of the second helium tank.

The pump line in the upper part of the first helium tank and/or in the partial section may be configured helically or with heat exchanger fins. In this way, the liquefaction/recondensation rate can be increased.

In the initial filling of the helium tanks with helium through a neck tube of the cryostat, a first tubing may be provided in a lower section of the first helium tank. A second tubing may be provided in a lower section of the second helium tank to fill the second helium tank. This allows the cryostat to be filled in a particularly efficient manner.

Further examples of the cryostat may be derived from the description and the drawings. The above-mentioned features and those further discussed below can be used individually in each case or can be combined into any desired combinations. The embodiments shown and described are not to be understood as an exhaustive list, but are given solely as examples for describing the invention.

For a magnet system that comprises one or more magnet coils in a cryostat (e.g., used for NMR measurements in a room temperature bore), the overall height of the cryostat may be limited in practice, e.g., by the ceiling height available to the user. Accordingly, a helium tank in the magnet system may also be restricted in size, limiting the hold time of the system. The present disclosure describes at least two concepts that overcome this limitation of the hold time. The concepts may also be used to achieve a reduction in overall height with the same hold time.

Cryostats designed with the described concepts all store liquid helium at >4 K not only in an upper part of a first helium tank, in which subcooled helium at <2.5 K is contained in a lower part, but also in a second helium tank. This additional supply of liquid helium may be used for the cooling of subcooled helium at <2.5 K by a Joule-Thomson cooling unit.

In one concept described herein, (normal) liquid helium (e.g., at approx. 4.2 K) is stored in two tanks, specifically in the upper region of a first (“inner”) helium tank and in a second (“outer”) helium tank. The second helium tank is arranged surrounding the first helium tank such that the overall height of the system is not increased by the second tank (although the diameter of the system increases slightly). The second tank is dimensioned so that that helium stored therein significantly increases the holding time of the system. If the gas chambers of the two tanks are connected to each other, helium that evaporates from the second helium tank can recondense in the first helium tank. This eliminates the need to actively transport helium from one tank into the other (e.g., by pumping).

The first helium tank is configured so that a large temperature gradient can form between a lower region and an upper region. This may be achieved by insertion of a “thermal barrier” having such favorable thermal insulation properties that the helium in the lower region (lower part) of the first helium tank can reach the superfluid state. The phase boundary between the normal and superfluid components is then within the thermal barrier.

In an NMR magnet system, the heat load on the lower region of the first helium tank is typically dominated by thermal radiation of the 80 K shield (radiation shield) in the central bore. Hereinafter, this heat load from the thermal radiation from the radiation shield is referred to as Q_{2K}. Heat is withdrawn from the lower region of the first helium tank by a Joule-Thomson (J-T) cooling unit. The available cooling capacity is referred to hereinafter as Q_{JT}. In thermal equilibrium, Q_{JT} may not be less than Q_{2K}.

The phase boundary between normal fluid helium and superfluid helium shifts by itself within the thermal barrier. The difference between Q_{JT} and Q_{2K} is exactly offset and the temperature in the lower region of the first helium tank remains constant. The heat flow Q_{TB} flowing over the thermal barrier is

Q_{TB}=Q_{JT}−Q_{2K}.

The helium flow through the J-T cooling unit is typically measured in ml/h, wherein the unit “ml” refers to milliliters of liquid helium at 4.2 K and atmospheric pressure (at this point, the density of liquid helium is 125.32 kg/m³). The enthalpy of liquid helium is −0.1622 kJ/kg at 4.2 K and atmospheric pressure, and 16.357 kJ/kg for gaseous helium at 2.17 K and a pressure of 10 mbar. Accordingly, for each milliliter of liquid helium drawn by the J-T cooling unit, a cooling capacity of 2.07 J is generated, i.e. Q_{JT}=2.07 J/ml.

The heat load on the upper region (upper part) of the first helium tank is hereinafter referred to as Q4_{KI}. It is assumed that this heat load is caused partially by thermal radiation from the central tube (i.e., the room temperature bore) on the upper region of the first helium tank, partially by thermal radiation from the thermal shield on the upper region of the first helium tank, and partially by thermal conduction via the neck tubes. Heat flows over the thermal barrier from the upper region of the first helium tank into the lower region of the first helium tank. Heat also flows from the upper region of the first helium tank into the pump line that pumps off helium for the J-T cooling unit, since cold helium gas is contained therein.

The cooling capacity Q_{PL}, that is available in this pump-out line is equivalent to the difference in enthalpy of gaseous helium (10 mbar) at 4.2 K and at 2.17 K. The two enthalpy values are 26.973 kJ/kg and 16.357 kJ/kg, respectively. In other words, the additionally available cooling capacity is 10.616 kJ/kg, or Q_{PL}=1.33 J/ml.

When the net heat load on the upper region of the first helium tank is positive, helium evaporates. When the net heat load is negative, helium that evaporates from the second helium tank can be recondensed in the first helium tank. The latent heat L of helium at atmospheric pressure and 4.2 K is 20.9172 kJ/kg or L=2.621 J/ml.

With the flow rates \dot{n}_{JT} (through the J-T cooling unit) and \dot{n}₁₋₀ (from the second helium tank to the first helium tank by evaporation/recondensation), one can write the following heat balance for the first tank:

\dot{n}₁₋₀·L=\dot{n}_{JT}·(Q_{JT}+Q_{PL})−(Q_{2K}+Q_{4Ki})

In normal operation, the helium filling level in the first helium tank should remain unchanged, i.e. \dot{n}₁₋₀=\dot{n}_{JT}. The flow rate is then

$${\dot{n}}_{jT} = \frac{{Q}_{2 K} + {Q}_{4 Ki}}{{Q}_{jT} + {Q}_{PL} - L} = \frac{{Q}_{2 K} + {Q}_{4 Ki}}{0.779 J \text{/} ml}$$

For a typical heat load Q_{2K}+Q_{4Ki}=250 mW, a flow rate of 1155 ml/h would therefore be required.

In order to reduce the required flow rate to a lower value of, e.g., 250 ml/h, the cryostat is designed so that the total heat load on the first helium tank (on both the upper and the lower regions) does not exceed 54 mW, i.e. the major portion of the heat load on the cold stages of the cryostat must be transferred into the second helium tank.

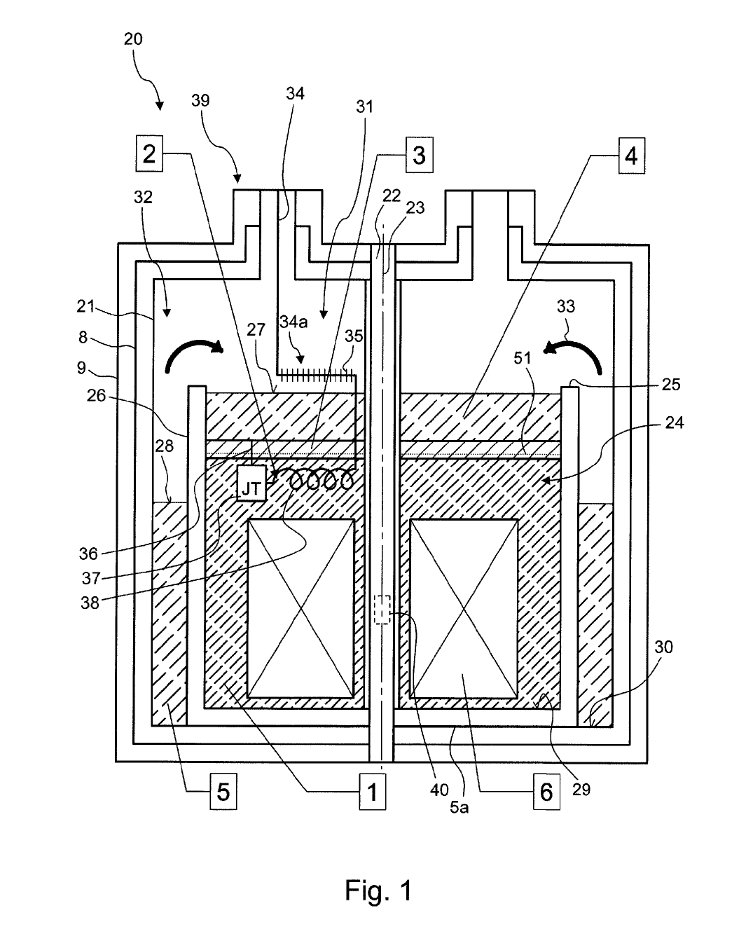

A first example of the cryostat will be explained in further detail below with reference to FIG. 1.

In this example, the cryostat 20 is contained in a vacuum vessel with a vacuum vessel wall 9, an inner wall 21, and a radiation shield 8 between the vacuum vessel wall 9 and an inner wall 21. The radiation shield 8 is in the vacuum. In practice, two or more radiation shields 8 can be provided. The radiation shield 8 may be cooled by liquid nitrogen (typically at approximately 80 K) (not shown in further detail). The cryostat 20 has a room temperature vertical bore 22. In this example, the cryostat 20 is configured in an essentially rotationally symmetrical manner around the central vertical axis of the room temperature bore 22.

In the interior of the cryostat 20 is configured a first helium tank 24, which is filled in a lower part 1 with superfluid helium (indicated by the dense cross-hatching) at a temperature of approximately 2.2 K. In this example, normal fluid helium (indicated by the less dense cross-hatching) is arranged in an upper part 4 of the first helium tank 24 at a temperature of approximately 4.2 K. The upper part 4 is almost completely filled, specifically up to just under an overflow edge 25. The upper part 4 and the lower part 1 are separated from each other by a liquid-permeable thermal barrier 3, for example, a glass-fiber-reinforced plastic plate with several vertical bores. In the thermal barrier 3, an interface 51 (shown as a dotted line close to the lower edge of the thermal barrier 3 in FIG. 1) runs between the superfluid helium and the normal fluid helium. It should be noted that temperature gradients may be established in the liquid helium inside the upper part 4 and within the thermal barrier 3 due to the temperature-dependent density of liquid helium.

In the interior of the cryostat 20, a second helium tank 5 is filled with normal fluid helium at a temperature of approximately 4.2 K. In FIG. 1, the second helium tank 5 is shown approximately two thirds full. The second helium tank 5 is arranged surrounding the first helium tank 24 and extends here in a vertical direction both over the lower part 1 and over the upper part 4 of the first helium tank 24.

The second helium tank 5 is separated from the first helium tank 24 by a wall 26 that is liquid-tight over its entire height. Therefore, the first liquid surface 27 in the first helium tank 24 may be significantly higher than the second liquid surface 28 in the second helium tank 5. It should be noted that in this example, the lower end 29 of the first helium tank 24 also lies somewhat above the level of the lower end 30 of the second helium tank 5. A plate 5a can then easily be mounted on the second helium tank 5, by means of which thermal radiation from the radiation shield 8 can be blocked before it impinges on the first helium tank 24.

A first gas chamber 31 for helium gas of the first helium tank 24 above the first liquid surface 27 and a second gas chamber 32 for helium gas of the second helium tank 5 above the second liquid surface 28 are connected with each other above the overflow edge 25, such that a common gas chamber is configured in the cryostat 20. This allows liquid helium from the second helium tank 5 to evaporate into the common gas chamber and recondense in the upper part 4 of the first helium tank 24, as shown by the arrows 33 indicating transport via the gas phase. In this example, recondensation may take place directly at the liquid surface 27 or in a partial section 34a of a cold pump line 34. The partial section 34a of the cold pump line 34 includes heat exchanger fins 35. Recondensed helium drips from the partial section 34a into the upper part 4. If too much helium reaches the upper part 4, liquid helium can flow over the overflow edge 25 into the second helium tank 5. The gas pressure in the common gas chamber is regulated, for example via a gas pressure sensor and an electric heater (not shown). Typically, the pressure is regulated to a pressure slightly (e.g., 10-50 mbar) above the ambient atmospheric pressure.

The pump line 34 is part of a Joule-Thomson cooling unit 2, which cools the superfluid helium in the lower part 1. In this example, the Joule-Thomson cooling unit 2 comprises a supply line 36 that leads into the upper part 4 of the first helium tank 24 in order to draw liquid helium. Alternatively, the joule-Thomson cooling unit 2 may draw superfluid helium from the lower part 1; in this case, the supply line 36 may be removed. The Joule-Thomson cooling unit 2 expands the liquid helium in a needle valve 37, which cools the helium down considerably. For this purpose, a sub-atmospheric pressure is applied at the needle valve 37 (e.g., approximately 10 mbar) via the pump line 34. A heat exchanger 38 may be integrated into the pump line 34 to ensure favorable transfer of the cooling capacity to the lower part 1. The heat exchanger 34 may be helically configured and may be arranged above a superconducting magnet coil 6. The pump line 34 leads through the thermal barrier 3, the upper part 4, and the first gas chamber 31, and through a neck tube 39 from the cryostat 20 out to a pump (not shown). The needle valve 37 can be supported in the first helium tank 24 with a further rod assembly (not shown) if necessary.

In the lower part 1 of the first helium tank 24, the superconducting magnet coil 6 is configured to produce a strong, uniform magnetic field in the room temperature bore 22 at a sample position for a sample 40 to be tested. For instance, the magnetic field may be used to investigate the sample 40 by NMR spectroscopy and/or imaging NMR.

Alternatively, the inlet of the J-T cooling unit 2 can be arranged so that helium is drawn in from the second helium tank 5. The J-T cooling unit 2 may be positioned below the second helium tank 5 in order to prevent the liquid level in the second helium tank 5 from dropping below the level of the J-T cooling unit 2. As the liquid helium is boiling, if the J-T cooling unit 2 were positioned above the second helium tank 5, helium gas would then form in the suction tube (supply line), which would considerably impair the functioning of the J-T cooling unit 2. In another alternative, the J-T cooling unit 2 may also be arranged in the bottom region of the first helium tank 24.

The lower region (lower part) of the first helium tank 24 is cooled by cold gas leaving the J-T cooling unit 2. The tubing between the second helium tank 24 and the J-T cooling unit 2 may be configured to provide sufficient thermal insulation. Moreover, the cryostat may be designed such that the needle valve is easily accessible from above, i.e., an access may be placed in such a way that the magnet coil does not block the path between the access opening at the upper end of the cryostat 20 and the J-T cooling unit 2.

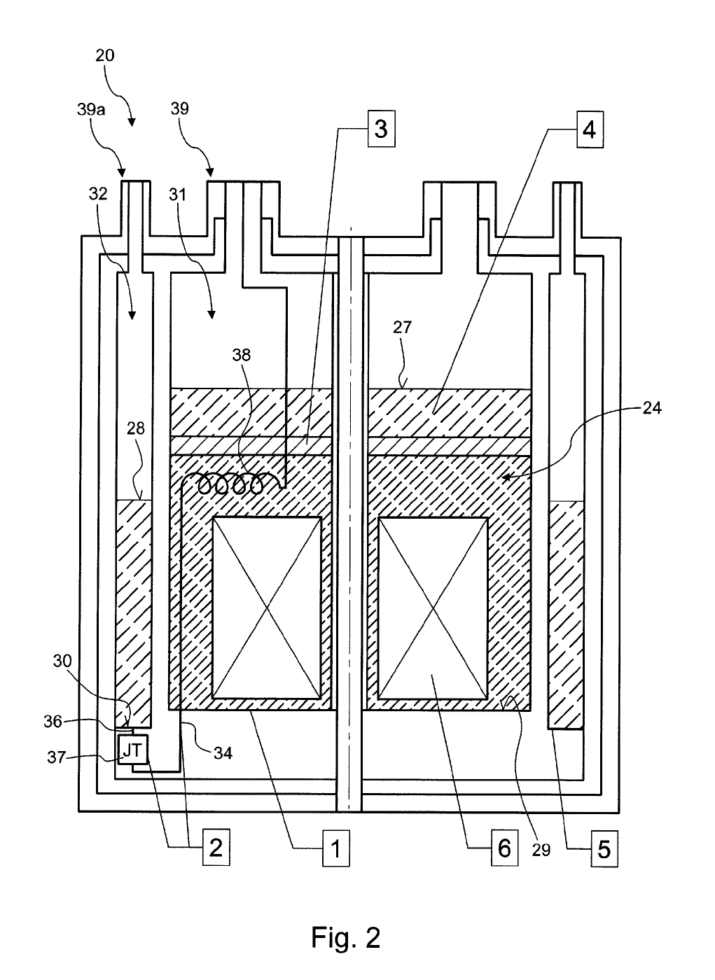

With reference to FIG. 2, a second example of a cryostat 20 is now presented. As the second example is similar to the first example of FIG. 1 in many aspects, only the main differences will be discussed in the following description. In the interior of the cryostat 20 of FIG. 2, a first helium tank 24 includes a lower part 1 filled with superfluid helium at approximately 2.2 K and an upper part 4 partially filled with normal fluid helium at approximately 4.2 K. The upper part 4 and the lower part 1 are separated by a thermal barrier 3 and the first helium tank 24 is filled with liquid helium from the lower end 29 to the first liquid surface 27. Moreover, a second helium tank 24 surrounds the first helium tank 24 in a ring shape, and is partially filled with normal fluid helium at approximately 4.2 K. In contrast to FIG. 1, the first helium tank 24 and the second helium tank 5 are completely sealed off from each other, and not only separated from each other in a fluid-tight manner below the first and second liquid surfaces 27 and 28. In particular, a first gas chamber 31 of the first helium tank 24 above the first liquid surface 27 and a second gas chamber 32 of the second helium tank 5 above the second liquid surface 28 are also separated from each other in a helium-gas-tight manner. The respective gas pressures in the gas chambers 31 and 32 are regulated separately, for example by means of gas pressure sensors and electric heaters (not shown), typically to a pressure slightly (usually 10-50 mbar) above the ambient atmospheric pressure.

The lower part 1 of the first helium tank 24 may be cooled with a Joule-Thomson cooling unit 2. In this example, the Joule-Thomson cooling unit 2 comprises a needle valve 37 that is positioned below the level of the lower end 30 of the second helium tank 5. The Joule-Thomson cooling unit 2 is connected via a supply line 36 to the lower end 30 of the second helium tank 5. The length of the supply line 36 is selected so as to be long enough to ensure sufficient thermal insulation from the second helium tank 5. As long as the second helium tank 5 is not exhausted, liquid helium from the second helium tank 5 can therefore flow into the needle valve 37. The liquid helium is expanded in the needle valve 37, providing cooling. From the needle valve 37, a pump line 34 leads into the lower part 1 of the first helium tank 24, where the pump line 34 is configured with a heat exchanger 38. The pump line 34 then leads through the upper part 4 of the first helium tank 24 and through the neck tube 39 out of the cryostat 20 to a pump (not shown), which provides a subatmospheric pressure (e.g., 10 mbar) in the pump line 34. The needle valve 37 is relatively easily accessible for adjusting the helium flow rate, as it is arranged outside the helium tanks 5 and 24.

It should be noted that in this example, the Joule-Thomson cooling unit 2 is supplied exclusively with helium from the second helium tank 5. In this case, the two helium tanks 24 and 5, are filled with liquid helium through separate accesses neck tubes 39 and 39a, respectively.

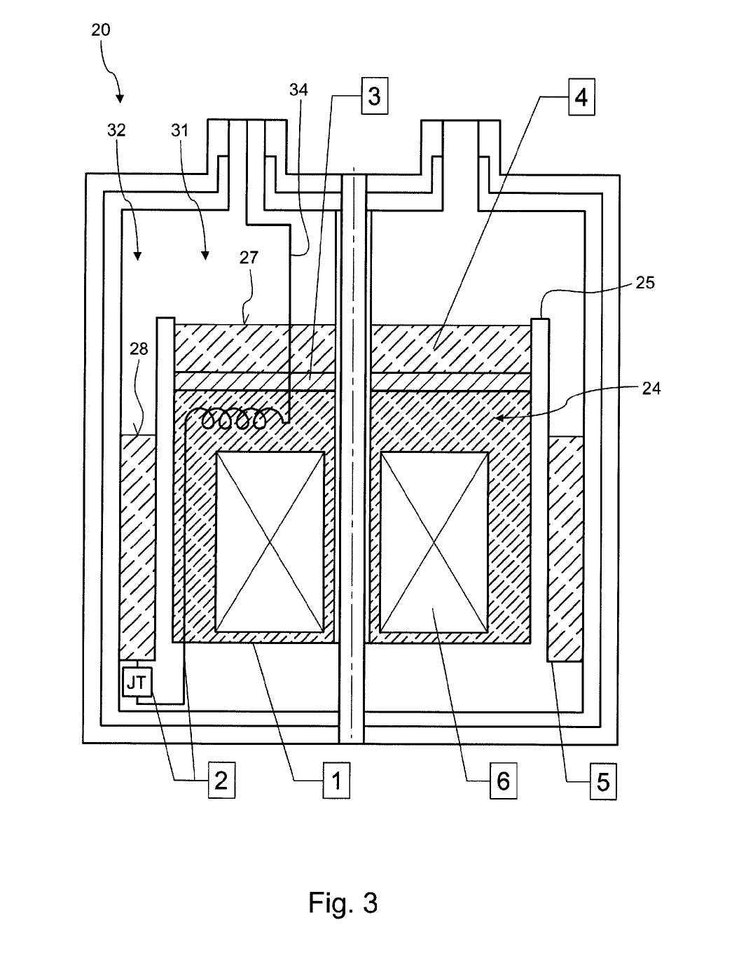

FIG. 3 shows a third example of a cryostat 20, which is similar to the second example shown in FIG. 2, so that only the differences are explained in the following.

In the example of FIG. 3, the first gas chamber 31 of the first helium tank 24 above the first liquid surface 27 and the second gas chamber 32 above the second liquid surface 28 are connected to each other. The connected gas chambers 31 and 32 form a common gas chamber of the two helium tanks 24 and 5. Additionally, an overflow edge 25 is configured between the first helium tank 24 and the second helium tank 5, so that liquid helium from the upper part 4 of the first helium tank 24 can flow off into the second helium tank 5. In this example, evaporated helium from the helium tanks 24 and 5 is recondensed primarily at the liquid surface 27 and at the pump line 34 in the first gas chamber 31 and drips into the upper part 4 of the first helium tank 24.

To efficiently fill both the first helium tank 24 and the second helium tank 5 with liquid helium, neck tubes may be arranged so that several neck tubes (or at least one neck tube 39) are directly above the first helium tank 24, and other neck tubes (or at least one other neck tube 39a) are directly above the second helium tank 5. Alternatively or additionally, tubing may be used to support filling of the helium tanks. For instance, tubing for filling the helium tanks 24 and/or 5 with liquid helium may be provided in the interior of the cryostat 20 such that the two helium tanks 24 and 5 can be filled from the same neck tube 39.

For example, the tubing can be arranged such that two different funnels (i.e., one for the first helium tank 24 and another for the second helium tank 5) can be reached by one neck tube 39. A helium transfer line is then placed in the corresponding funnel in order to fill the respective tank.

Alternatively, the transfer line and a counterpart thereof on the cryostat side may be configured so that one can determine by the rotational position of the transfer line whether the first helium tank 24 or the second helium tank 5 is to be filled with liquid helium.

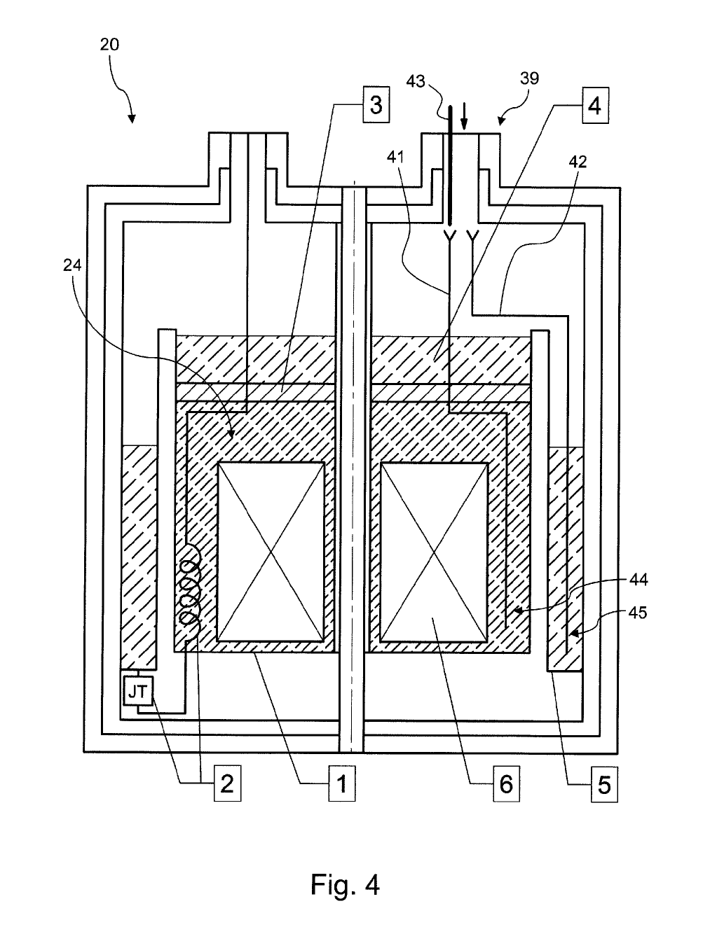

FIG. 4 shows a fourth example of a cryostat 20, which largely corresponds to the example of FIG. 3, so that in the following, only the differences will be discussed.

In this example, a first tubing 41 and a second tubing 42 are arranged in the cryostat 20. Each tubing 41, 42 has its own filling funnel below the neck tube 39, via which or in which a helium transfer line 43 extending through the neck tube 39 can be arranged. Liquid helium flowing out at a lower end from the helium transfer rod 43 can then flow into the filling funnel selected by placement of the helium transfer rod 43.

The first tubing 41 leads into the first helium tank 24 through the upper part 4 and the thermal barrier 3 into the lower part 1, and opens into a lower section 44 of the first helium tank 24, typically into the lower quarter of the lower part 1. The second tubing 42 leads into the second helium tank 5, and opens into a lower section 45 of the second helium tank 5, typically into the lower quarter of the second helium tank 5.

In the example shown in FIG. 4, the heat exchanger 38 is arranged in the lower part 1 adjacent to the magnet coil 6, and not above the magnet coil 6. This allows the overall height of the cryostat 20 to be reduced in some cases. However, the heat exchanger 38 may also be arranged above the magnet coil 6, i.e., similar to the configuration shown in FIG. 1.

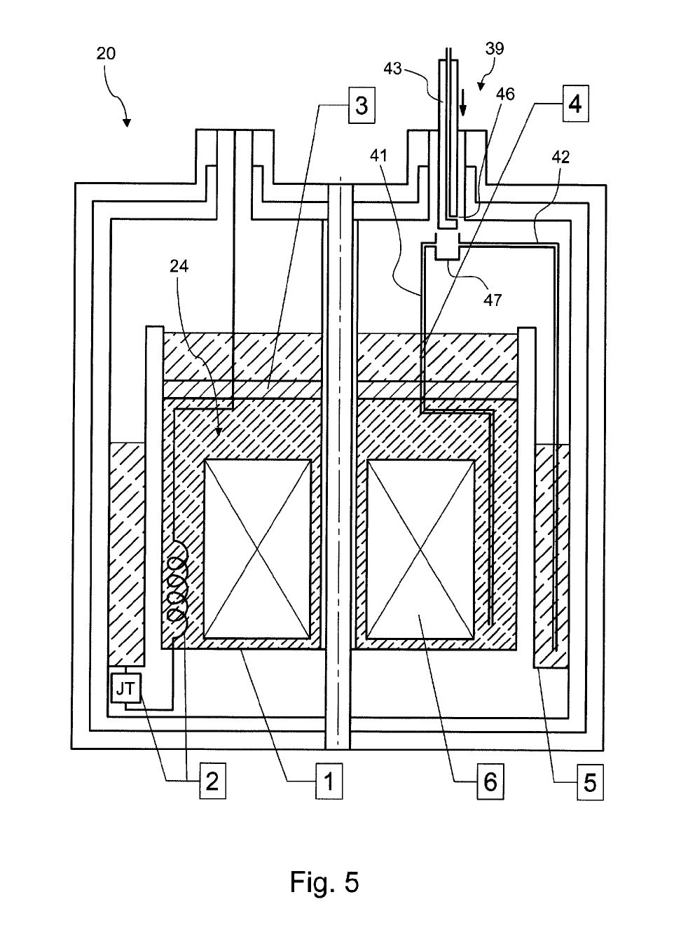

In a fifth example of the cryostat 20 shown in FIG. 5, which is in turn similar to the example of FIG. 4, so that only the differences will be discussed, the helium transfer rod 43 is configured with a lateral outlet 46 near its lower end. The first tubing 41 and the second tubing 42 are connected to a coupling station 47 at their upper ends. The coupling station 47 is arranged under the neck tube 39. The coupling station 47 forms a receptacle for the helium transfer line 43, which may be inserted from above through the neck tube 39 into the coupling station 47.

In this case, the helium transfer line 43 allows liquid helium to flow into the first tubing 41 in a first orientation. Alternatively, the helium transfer line 43 allows liquid helium to flow into the second tubing 42 in a second orientation. As shown in FIG. 5, the helium transfer rod 43 is shown in the rotational position of the second orientation, such that the helium transfer rod 43 only needs to be lowered in the coupling station 47 in order to fill the second helium tank 5 via the second tubing 42. In a rotationally symmetrical (circular) configuration of the coupling station 47 or the receiving opening thereof and the helium transfer line 43, the helium transfer rod 43 can be rotated in the coupling station 47 in order to change the orientation. Alternatively, the helium transfer line 43 and the coupling station 47 are not configured in a rotationally symmetrical manner, and the helium transfer rod 43 is brought into the desired orientation by the coupling station 47 and then inserted in place. The helium transfer rod 43 is then held in place in the coupling station 47 in a non-rotatable manner.

In another example. a cryostat 20 may be operated in combination with an active cooling system (active cooling device, “cooler”), such as a pulse tube cooler.

In this example, particular attention should be paid to the scenario of a cooler failure. In the event of a failure of the active cooler, thermal conduction via the cold finger(s) of the cooler leads to a considerable heat load, which should be transferred to the extent possible to the storage tank (i.e., the second helium tank 5). This can be achieved by arranging the active cooler above the second helium tank 5 and configuring the connection of the gas chambers of the first helium tank 24 and the second helium tank 5 to be as tight as possible. A lower limit on the tightness of the connection between the helium tanks may be derived from the requirement that in some emergency scenarios (e.g. a loss of vacuum) helium should be able to flow through the connection with little pressure loss).

A heat load that arises from thermal conduction in the neck tubes can be transferred to the second tank by means of a connecting element composed of a highly conducting material (such as copper).

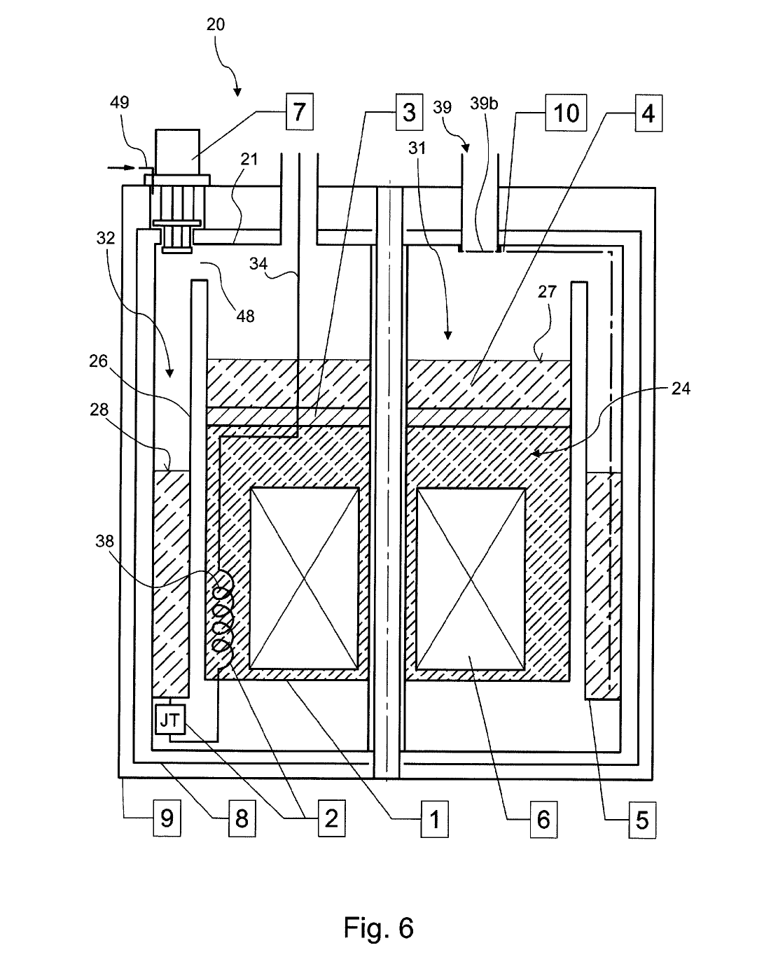

FIG. 6 shows a sixth example of a cryostat 20, which is similar to the cryostat of FIG. 3, so that only the differences will be discussed.

An active cooling device 7, which is in addition to the Joule-Thomson cooling unit 2, is arranged above the second helium tank 5. The active cooling device 7 may be a pulse tube cooler or a cold head thereof. Between the second helium tank 5 and the first helium tank 24, a wall 26 is configured that extends up to just under the lid of the inner receptacle wall 21. The wall 26 shades a majority of the first helium tank 24, in particular the majority of the first liquid surface 27, from the active cooling device 7. The relatively small gap 48 between the wall 26 and the lid of the inner receptacle wall 21 minimizes convection of helium gas. Moreover, a connection 10 having good thermal conductivity (e.g., composed of copper) is connected from a lower closure lid 39b on the neck tube 39 to the liquid helium in the second helium tank 5. These measures ensure that a heat load (for example on failure of the cooling device 7, or also on failure of the Joule-Thomson cooling unit 2) is transferred primarily to the second helium tank 5, and only to a lesser degree to the first helium tank 24. Accordingly, the superconducting magnet coil 6 is protected from the heat load, providing the superconducting magnet coil 6 a longer hold time, particularly in the case of failure of the active cooling device 7.

During normal operation, the active cooling device 7 recycles helium gas that was drawn off by the pump line 34 and returned to the cryostat 20 via a supply line 49. The helium gas liquefies on the lowest cooling stage of the active cooling device 7 and drips into the second helium tank 5, from where it can again be drawn off by the Joule-Thomson cooling unit 2. The cryostat 20 can therefore be operated with a closed helium circuit, i.e. without helium consumption/loss. In FIG. 6, as with FIG. 5, the heat exchanger 38 is again positioned adjacent to the superconducting magnet coil 6 in the lower part 1 of the first helium tank 24.

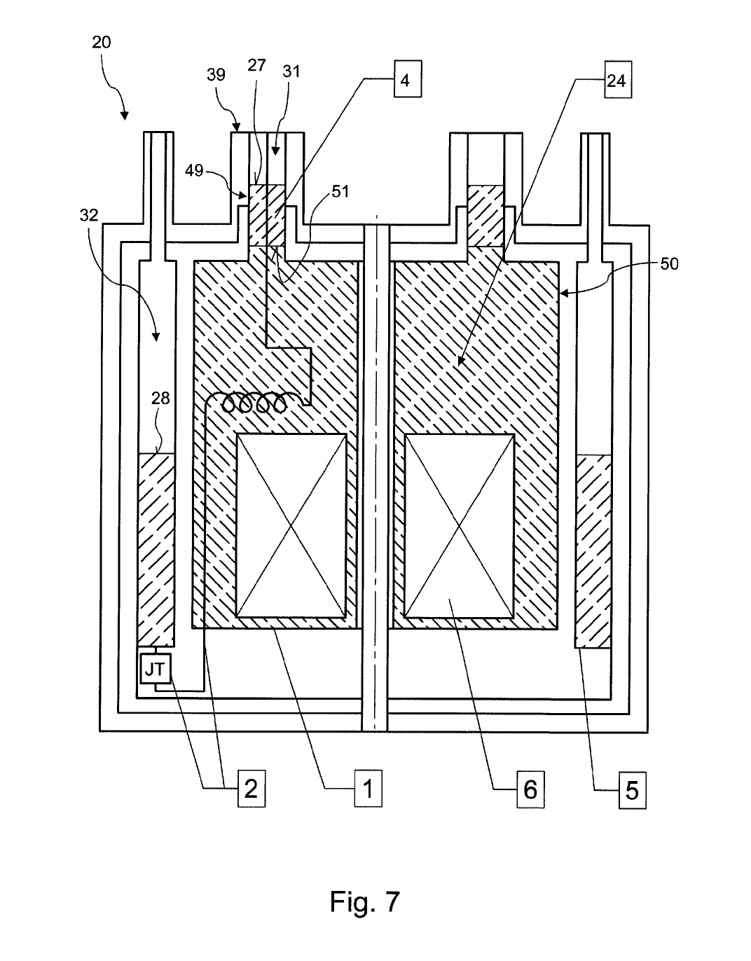

FIG. 7 shows a seventh example of a cryostat 20, which is similar to the example of FIG. 2, so that again, only the differences will be discussed.

In this example, the first helium tank 24 comprises an access tube 49 in a neck tube 39. A section 50 of the first helium tank 24 that is positioned under the access tube 49 is wider than the access tube 39. The section 50 is completely filled with superfluid helium at approximately 2.2 K, as is a lower section of the access tube 39 up to an interface 51. Normal fluid helium at approximately 4.2 K fills the access tube 39 above the interface 51 up to the first liquid surface 27.

Because of the small (horizontal) cross-sectional area of the access tube 49, the heat input through the interface 51 from the upper part 4 (filled with normal fluid helium) to the lower part 1 (filled with superfluid helium) of the first helium tank 24 is so low that the cooling capacity of the Joule-Thomson cooling unit 2 can compensate for it. In one example, cross-sectional area of the access tube 49 is a maximum of 1/10 of the cross-sectional area of the area 50. Alternatively, the ratio of the cross-sectional areas may be a maximum of 1/20, or up to a maximum of 1/50.

In the example shown in FIG. 7, the first gas chamber 31 of the first helium tank 24 above the first liquid surface 27 is separate from the second gas chamber 32 of the second helium tank 5 above the second liquid surface 28. Accordingly, the Joule-Thomson cooling unit 2 draws directly from the second helium tank 5.

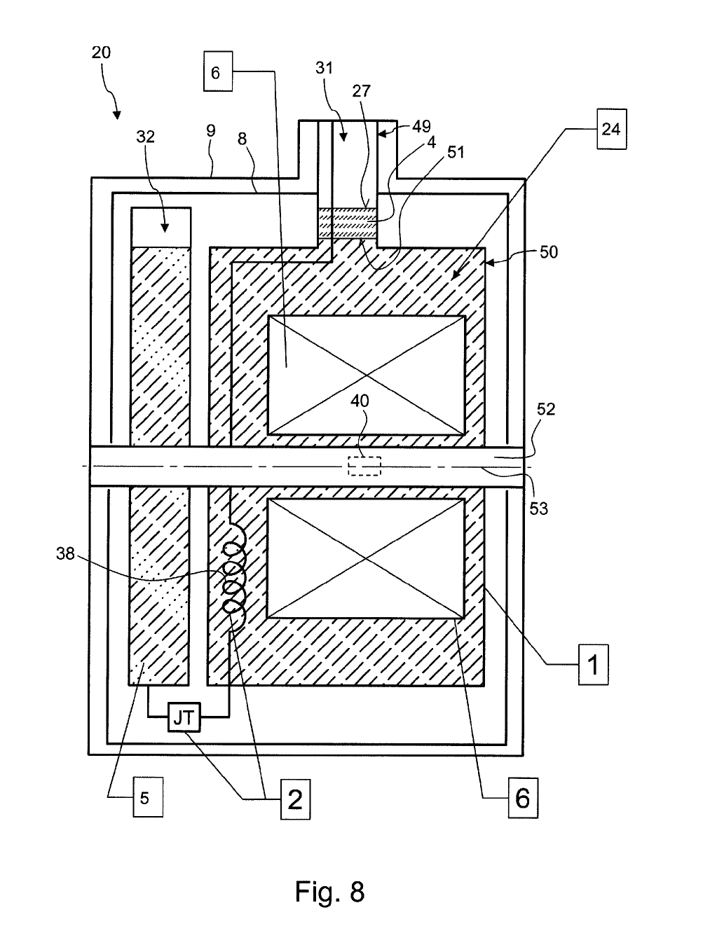

FIG. 8 shows an eighth example of a cryostat 20, similar to the example shown in FIG. 2, so that in the following only the differences will be discussed.

The cryostat 20 with a vacuum vessel wall 9 and a radiation shield 8 has a room temperature horizontal bore 52 that extends through both the first helium tank 24 and the second helium tank 5. The second helium tank 5 is arranged laterally adjacent to the first helium tank 24, and extends essentially over the same vertical area as the first helium tank 24. A sample 40 arranged at a sample position in the room temperature bore 52 may be exposed by the superconducting magnet coil 6 to a strong, uniform magnetic field. The cryostat 20 may be essentially configured in a rotationally symmetrical manner with respect to the central, horizontal axis 53.

Similar to the example shown in FIG. 7, the first helium tank 24 comprises an access tube 49 that is narrowed with respect to a section 50 lying thereunder, and the interface 51 between the normal fluid and the superfluid helium is positioned in the access tube 49. In this example, the liquid surface 27 of the normal fluid helium lies below the part of the radiation shield 8 on the upper side.

The upper part 4 of the first helium tank 24 contains a relatively small amount of liquid helium. In contrast, the second helium tank 5 may be filled with a large amount of liquid helium, which can be used by the Joule-Thomson cooling unit 2 for cooling the lower part 1 of the first helium tank 24 with the magnet coil 6. In this example, the heat exchanger 38 is arranged laterally adjacent to the magnet coil 6. The gas chambers 31 and 32 of the first helium tank 24 and the second helium tanks 5, respectively are separated from each other in this example.

In summary, the techniques presented herein describe a cryostat for subcooled (<2.5 K) liquid helium, which is typically used for cooling of a superconducting magnet coil. The cryostat includes two helium tanks that do not communicate with each other with regard to the respectively contained liquid helium. A Joule-Thomson cooling unit having a heat exchanger in the lower part of the first helium tank uses the liquid helium (>4 K) stored in the second helium tank (storage tank) in order to cool the subcooled liquid helium in the lower part of the first helium tank. For this purpose, the Joule-Thomson cooling unit may directly draw liquid helium from the second helium tank. Alternatively, the Joule-Thomson cooling unit may draw liquid helium from the first helium tank (typically from an upper part with liquid helium at >4 K), and helium can be transferred via the gas phase from the second helium tank to the first helium tank. The second helium tank allows an extremely long period of time during which the subcooled liquid helium of the first helium tank can be cooled by means of a helium supply in the cryostat. The second helium tank can be positioned at least partially adjacent to the first helium tank, in particular surrounding the first helium tank, in order to lower the overall height of the cryostat.

Within the framework of the cryostat described herein, the holding time of a subcooled magnet system can be increased by increasing the volume of the helium storage tank. The increased holding time is achieved without changing the overall height by the second helium tank is thermally insulated from the first helium tank and positioned adjacent to or surrounding the first helium tank, which holds the magnet coil. In some examples, helium that evaporates from the second helium tank can recondense in the first helium tank. The cryostat may be designed such that the total heat load is largely accounted for by the second helium tank. The helium required for operation of the J-T cooling unit may be drawn from the second helium tank. A cryostat according to the invention may also be operated in combination with an active cooling device, such as a pulse tube cooler. A further advantage of the cryostat described herein is that in the case of a magnet quench, only helium from the first helium tank is lost, since the second helium tank can be thoroughly thermally insulated from the first helium tank, and the heat generated in the magnet quench is therefore not transferred into the second helium tank.

What is claimed is:

1. A cryostat comprising:
a first helium tank, which is filled in a lower part with subcooled liquid helium at a temperature <2.5 K, and which is filled in an upper part at least partially with normal fluid helium, such that the lower part of the first helium tank is continuously filled with liquid helium between a lower end of the lower part and a first liquid surface in the upper part;
a Joule-Thomson cooling unit configured to cool the subcooled liquid helium in the lower part of the first helium tank by expansion of helium via a heat exchanger; and
a second helium tank, which is at least partially filled with liquid helium, such that the second helium tank is continuously filled with liquid helium between a lower end of the second helium tank and a second liquid surface in the second helium tank, wherein the first helium tank and the second helium tank are separated from each other in a liquid-tight manner at least below the first liquid surface and the second liquid surface, and wherein the Joule-Thomson unit withdraws liquid helium from the second helium tank either directly via drawing liquid helium from the second helium tank, or indirectly via evaporation of liquid helium from the second liquid surface in the second helium tank recondensing the evaporated helium in the upper part of the first helium tank, and drawing liquid helium from the first helium tank.

2. The cryostat according to claim 1, wherein the second helium tank is arranged either at least partially laterally adjacent to the first helium tank or at least partially surrounding the first helium tank.

3. The cryostat according to claim 1, wherein the first helium tank and the second helium tank are arranged such that the first liquid surface of the normal fluid helium in the first helium tank is at a higher level than the second liquid surface of the liquid helium in the second helium tank.

4. The cryostat according to claim 1, wherein the second helium tank holds at least three times as much liquid helium as the upper part of the first helium tank.

5. The cryostat according to claim 1, further comprising a thermal barrier arranged between the upper part of the first helium tank and the lower part of the first helium tank, wherein the thermal barrier enables a temperature gradient of at least 1 Kelvin to be produced, generating an interface between the subcooled liquid helium and normal fluid helium.

6. The cryostat according to claim 1, wherein the first helium tank further comprises an access tube that is narrower than a section of the first helium tank lying thereunder, such that a temperature gradient of at least 1 Kelvin is produced in the access tube, generating an interface between the subcooled liquid helium and normal fluid helium in the access tube.

7. The cryostat according to claim 1, further comprising a room temperature vertical bore, wherein the first helium tank is arranged around the room temperature vertical bore and the second helium tank is arranged around the first helium tank.

8. The cryostat according to claim 1, further comprising a room temperature horizontal bore, wherein the second helium tank is arranged horizontally adjacent to the first helium tank.

9. The cryostat according to claim 8, wherein the room temperature horizontal bore extends through both the first helium tank and the second helium tank.

10. The cryostat according to claim 1, wherein the Joule-Thomson cooling unit is configured to draw in liquid helium directly from the lower end of the second helium tank.

11. The cryostat according to claim 1, wherein a first gas chamber of the first helium tank is connected to a second gas chamber of the second helium tank in such a manner as to carry helium gas.

12. The cryostat according to claim 11, wherein a helium flow rate from the first helium tank to the Joule-Thomson cooling unit is selected to enable liquid helium to evaporate from the second helium tank and recondense in the upper part of the first helium tank.

13. The cryostat according to claim 11, wherein the upper part of the first helium tank is separated from the second helium tank by a wall with an overflow edge over which the normal fluid helium can overflow from the first helium tank into the second helium tank.

14. The cryostat according to claim 1, further comprising an active cooling device configured to liquify helium that evaporates from the first helium tank or the second helium tank.

15. The cryostat according to claim 14, wherein the active cooling device comprises a pulse tube cooler.

16. The cryostat according to claim 14, wherein the active cooling device is arranged in the cryostat such that failure of the active cooling device brings a greater heat load on the second helium tank and a lesser heat load on the first helium tank (24), such that failure of the active cooling device causes more helium to evaporate from the second helium tank than from the first helium tank.

17. The cryostat according to claim 16, wherein the active cooling device is arranged above the second helium tank, and the first liquid surface is completely or predominantly shaded from the active cooling device.

18. The cryostat according to claim 1, further comprising a pump line of the Joule-Thomsen cooling unit that runs through the upper part of the first helium tank with a partial section of the pump line running in a gas above the first helium tank so that helium liquefied on an outer side of the pump line in the partial section of the pump line drips from the pump line into the upper part of the first helium tank.

19. The cryostat according to claim 18, wherein the partial section of the pump line is configured helically or with heat exchanger fins.

20. The cryostat according to claim 1, further comprising:
a first tubing that extends into a lower section of the first helium tank for initially filling the first helium tank; and
a second tubing that extends into a lower section of the second helium tank for initially filling the second helium tank.
